(19) United States
(12) Patent Application Publication
(10) Pub. No.: US 2016/0233822 A1
(43) Pub. Date: Aug. 11, 2016

(54) PHOTOVOLTAIC GROUNDING SYSTEM AND METHOD OF MAKING SAME

(71) Applicant: General Electric Company, Schenectady, NY (US)

(72) Inventors: Charles Steven Korman, Niskayuna, NY (US); Neil Anthony Johnson, Niskayuna, NY (US)

(21) Appl. No.: 15/134,933

(22) Filed: Apr. 21, 2016

Related U.S. Application Data
(62) Division of application No. 14/026,853, filed on Sep. 13, 2013.
Application No. 14/026,853 is a continuation-in-part of application No. 13/079,900, filed on Apr. 5, 2011, now abandoned.

(51) Int. Cl. H02S 20/23; H02S 30/10; H01L 31/18; H02S 40/32; H02S 40/34

(52) U.S. Cl. CPC H02S 20/23; H02S 40/32; H02S 40/34; H01L 31/18; H02S 30/10

(57) ABSTRACT

A photovoltaic (PV) grounding system includes a first grounding path comprising an electrical connection between a plurality of support bars of a rail system and a connection box coupled to the rail system. The PV grounding system also includes a second grounding path comprising an electrical connection between the connection box and a plurality of PV modules disposed within the rail system, the second ground path extending from micro-inverter ground leads of the plurality of PV modules, through an extension harness electrically connected to the plurality of PV modules, to a ground connection within the connection box. The PV grounding system further includes a third grounding path that includes an electrical connection between the ground connection within the connection box and a building load panel. The first grounding path, the second grounding path, and the third grounding path are electrically connected within the connection box.

### CROSS REFERENCE TO RELATED APPLICATION

The present application is a divisional of and claims priority to U.S. Non-Provisional application Ser. No. 14/026,853, filed Sep. 13, 2013, which is a continuation-in-part of and claims priority to U.S. Non-Provisional application Ser. No. 13/079,900, filed Apr. 5, 2011, the disclosures of which are incorporated herein by reference in their entireties.

### BACKGROUND OF THE INVENTION

Embodiments of the invention relate generally to photovoltaic (PV) systems and more particularly to a system and method for grounding a PV system.

PV systems include PV modules arranged in arrays that generate direct current (DC) power, with the level of DC current being dependent on solar irradiation and the level of DC voltage dependent on temperature. Typical PV systems include modules with metal frames and metal mounting racks that are in exposed locations such as rooftops where they are subject to lightning strikes, or are located near high voltage transmission lines that may come into contact with components of the PV system in the event of high winds, etc. The metal frames of the PV modules are typically made of an anodized aluminum to protect the frames from exposure to the elements. To mitigate the impacts of line surges or unintentional contact with high voltage lines, the metal components of PV systems are grounded to create a lower impedance path to ground so that, in the case of any system component that is shorted to the metal frame or rail, the short circuit current will be shunted to ground through the ground circuit path rather than through a person working on the PV system.

To meet the national electrical code (NEC), special DC wiring and grounding specifications must be met for DC module strings capable of producing voltages as high as 600 volts. A failure in the insulating material of the PV laminate could allow the frame to be energized up to 600V DC. To satisfy existing electrical codes and standards, the frame of each PV module is typically grounded using a heavy (e.g., #8 gauge) copper wire and a 10-32 screw that can cut into the frame. For module frames with anodized surfaces, additional components, such as washers/connectors (sometimes called “weebs”) are used to penetrate into the metal frame and provide a reliable electrical contact. These weebs are installed between adjacent PV module frames on-site and operate to create a direct electrical connection between adjacent PV modules. In a separate installation step, grounding wires are used to connect the metal case of the micro-inverter of each module to the respective module frame.

Because the aluminum frames of modules in a PV array are typically anodized, grounding the frames does not ensure that the metal mounting racks or rails of the PV system are grounded. Thus, PV systems include additional heavy wire ground leads (e.g., #8 gauge copper wire) that are attached to each separate rail section at the installation site and brought to a common point. All other metal components of the mounting system are also individually grounded to the system ground by dedicated ground connections. Because all of these ground connections are made on-site by an installer who has specialized training in solar installations, the process for grounding the PV system accounts for 25-30 percent of the time and cost of the overall installation of the PV system.

Therefore, it would be desirable to provide a PV system with simplified ground connections for the metal components of the PV system that meets NEC standards and reduces the time and cost of on-site installation of the PV system.

### BRIEF DESCRIPTION OF THE INVENTION

In accordance with one aspect of the invention, a photovoltaic (PV) grounding system includes a first grounding path comprising an electrical connection between a plurality of support bars of a rail system and a connection box coupled to the rail system. The PV grounding system also includes a second grounding path comprising an electrical connection between the connection box and a plurality of PV modules disposed within the rail system, the second ground path extending from micro-inverter ground leads of the plurality of PV modules, through an extension harness electrically connected to the plurality of PV modules, to a ground connection within the connection box. The PV grounding system further includes a third grounding path that includes an electrical connection between the ground connection within the connection box and a building load panel. The first grounding path, the second grounding path, and the third grounding path are electrically connected within the connection box.

In accordance with another aspect of the invention, a method of manufacturing a photovoltaic (PV) grounding system includes providing a first PV panel having a frame, electrically coupling a metal housing to the frame of the first PV panel, the metal housing having a micro-inverter disposed therein, and coupling a first end of a micro-inverter ground lead to the metal housing. The method also includes assembling a plurality of support bars to form an equipotential rail system, positioning the first PV panel within the rail system, and coupling a second end of the micro-inverter ground lead to an extension harness, the extension harness including a plurality of connection modules electrically coupled to an extension ground lead of the extension harness. The method further includes coupling a connector box to the rail system such that the connector box is at equipotential with the rail system, positioning a first end of the extension harness within the connector box, positioning a load ground lead of a load panel within the connector box, and coupling the load ground lead to the extension ground lead within the connector box.

In accordance with yet another aspect of the invention, a photovoltaic (PV) system includes an equipotential rail system and a first PV circuit. The first PV circuit includes a first multi-module wiring harness disposed within the rail system, a first plurality of PV modules disposed within the rail system, each of the first plurality of PV modules having an internal ground lead electrically coupled to the first wiring harness, and a first connection box mechanically and electrically coupled to the rail system and a ground lead wire of the first wiring harness. The PV system further includes a first home run cable comprising a first end and a second end, the first end mechanically and electrically coupled to the first connection box, and the second end coupled to a ground connection of a circuit breaker panel.

These and other advantages and features will be more readily understood from the following detailed description of preferred embodiments of the invention that is provided in connection with the accompanying drawings.

### BRIEF DESCRIPTION OF THE DRAWINGS

The drawings illustrate embodiments presently contemplated for carrying out the invention.

In the drawings:

FIG. 1 is a front perspective view of a photovoltaic (PV) system, according to an embodiment of the invention.

FIG. 2A is an exploded perspective view of a portion of the PV system illustrated in FIG. 1, according to an embodiment of the invention.

FIG. 2B is an enlarged view of portion 2B in FIG. 2A showing a connector of an extension harness of the PV system.

FIG. 3A is a rear schematic view of a PV module useable with the PV system shown in FIG. 1, according to an embodiment of the invention.

FIG. 3B is an enlarged view of portion 3B in FIG. 3A showing lead wires within a wiring harness of the PV module.

FIG. 4 is a schematic diagram of a common connector box of FIG. 4 useable with the PV system of FIG. 1, according to an embodiment of the invention.

FIG. 5 is a schematic diagram illustrating a grounding path of the components of the PV system of FIG. 1, according to an embodiment of the invention.

FIG. 6 is a schematic diagram of a multi-circuit PV system, according to an embodiment of the invention.

### DETAILED DESCRIPTION

Embodiments of the present invention provide for a simplified system for grounding a photovoltaic (PV) system.

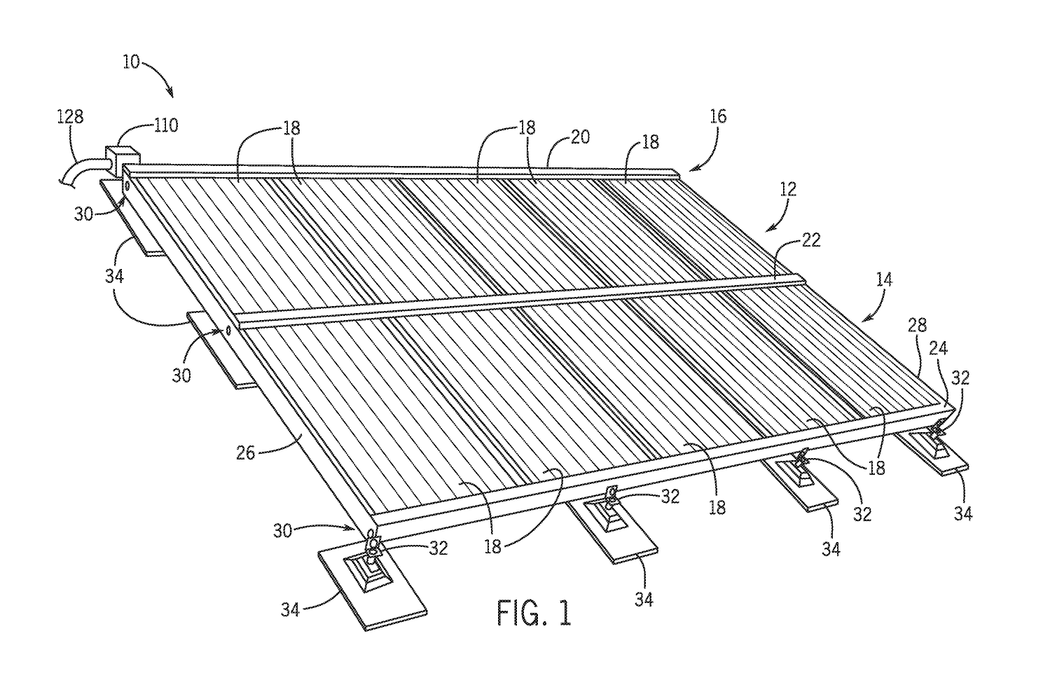

Referring now to FIG. 1, a photovoltaic (PV) system 10 is illustrated according to an embodiment of the invention. PV system 10 includes a pair of basic building block assemblies 12, 14 and a rail system 16 that includes a number of support bars, as described in detail below. In the embodiment shown in FIG. 1, each basic building block assembly 12, 14 of a photovoltaic (PV) mounting system 10 includes a row of five (5) PV modules 18. However, one skilled it the art will appreciate that embodiments of the invention are not limited to a basic building block assembly having a particular number of PV modules 18. Thus, according to alternative embodiments, basic building block assemblies 12, 14 may include any desirable number of PV modules 18 depending on design specifications and applicable limitations imposed by the National Electrical Code (NEC).

Rail system 16 of PV system 10 has an asymmetric design that allows n rows of PV modules 18 to be supported by n+1 horizontal rail sections. For example, a PV system having two (2) rows of PV modules would be supported by three (3) rail sections. In one embodiment, rail system 16 includes five (5) support bars including a top metallic rail section 20, a central metallic rail section 22, a bottom metallic rail section 24, a first grounding bar 26, and a second grounding bar 28. As shown in FIG. 1, first and second grounding bars or support bars 26, 28 are positioned in a perpendicular arrangement to rail sections 20, 22, 24. Fastener assemblies 30 mechanically and electrically couple first and second grounding bars 26, 28 to respective ends of rail sections 20, 22, 24, as described in additional detail below. L-brackets 32 mount metallic rail sections 20 to mounting stanchions 34.

According to one embodiment, top, central, and bottom rail sections 20, 22, 24 and first and second grounding bars 26, 28 are constructed of an anodized metal, such as, for example, aluminum. In such an embodiment, fastener assemblies 30 include self-tapping screws or components constructed to break through the anodized surface of grounding bars 26, 28 during the assembly process in order to create an electrical connection between the base metal of grounding bars 26, 28 and the base metal of rail sections 20, 22, 24. First and second grounding bars 26, 28 thus act to electrically bond together top, central, and bottom rail sections 20, 22, 24. Because rail sections 20, 22, 24 and grounding bars 26, 28 are electrically coupled together at a low resistance, the components within rail system 16 are at the same electric potential. In other words, the components within rail system 16 are at equipotential.

According to one embodiment, first and second grounding bars 26, 28 and top, central, and bottom rail sections 20, 22, 24 include predrilled holes for fastener assemblies 30 to ensure correct physical spacing between rail sections 20, 22, 24 and reduce installation errors.

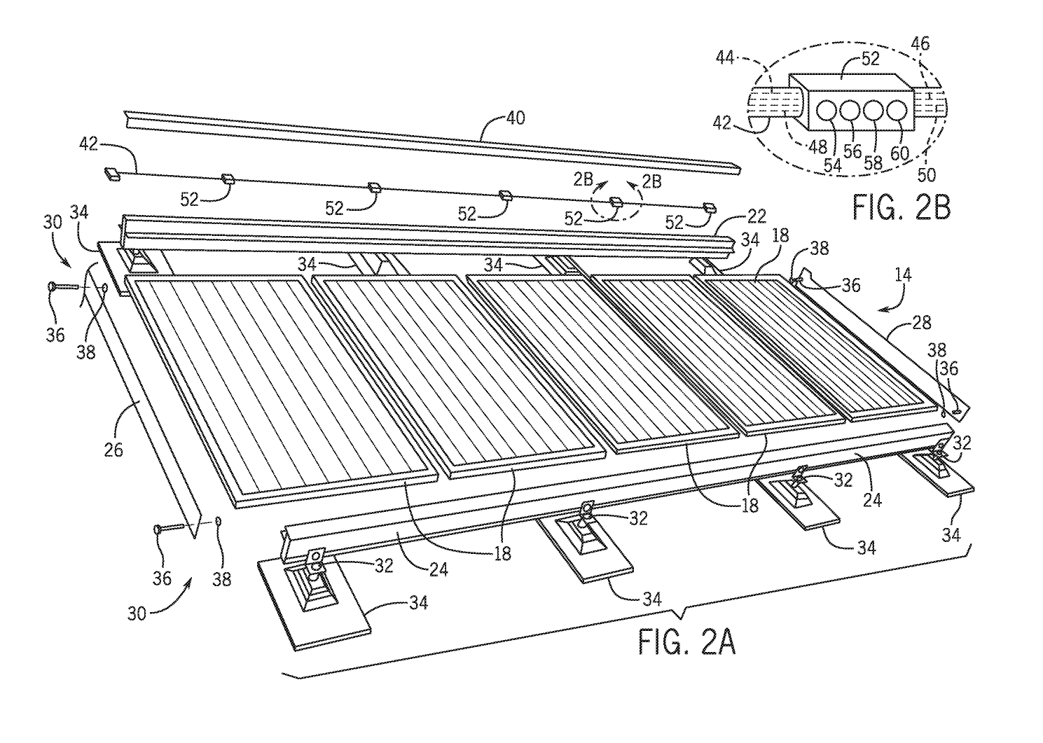

An exploded perspective view of a portion of PV system 10 associated with basic building block assembly 14 is illustrated in FIG. 2A. In one embodiment, fastener assemblies 30 include respective pairs of fasteners 36 and star washers 38 that mechanically and electrically couple first and second grounding bars 26, 28 to top metallic rail section 20 and bottom metallic rail section 24.

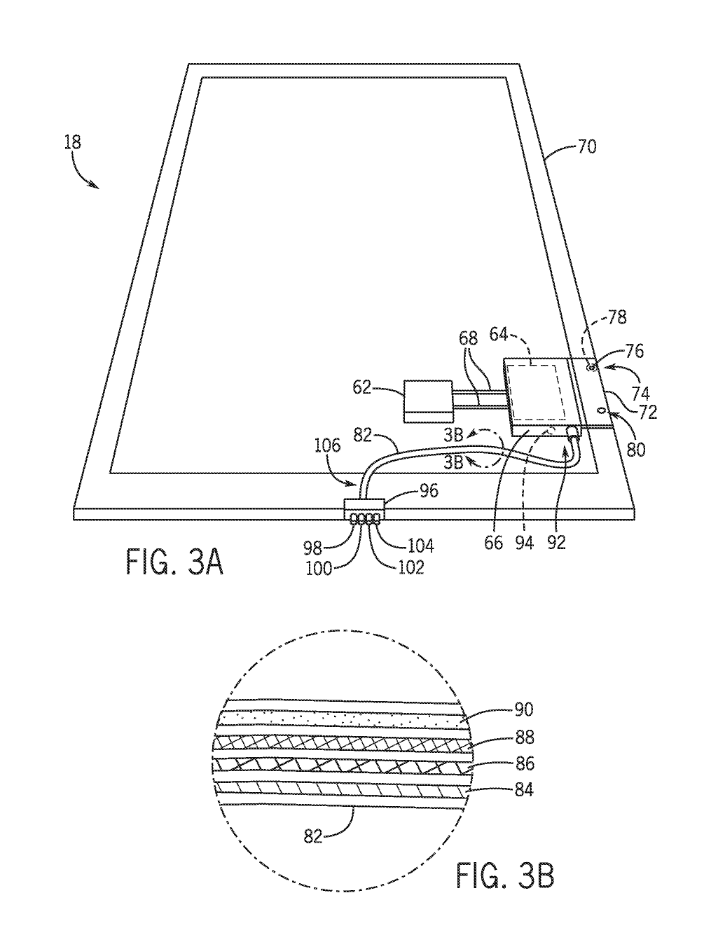

A locking cover assembly 40 is mounted to central metallic rail section 22 for holding PV modules 18 in place. In one embodiment, locking cover assembly 40 includes an individual locking cover for each PV module 18, which allows an individual PV module 18 to be removed for maintenance. Locking cover assembly 40 is attached to central metallic rail section 22 with fasteners that penetrate the anodized surfaces of rail section 22 and locking cover assembly 40 during installation to create a grounded connection between rail section 22 and locking cover assembly 40. Central metallic rail section 22 also includes a multi-module AC extension harness 42, which is secured to central metallic rail section 22 using known fasteners such as, for example, clips (not shown). According to one embodiment AC extension harness 42 includes a pair of AC lead wires 44, 46, a neutral lead wire 48, and an extension ground lead wire 50. In one embodiment AC lead wires 44, 46 are 120 volt AC leads. A number of slotted connectors 52 are positioned along the length of AC extension harness 42 to interface with respective PV modules 18, as described in more detail with respect to FIGS. 3A and 3B. Each connector 52 includes four slots 54, 56, 58, 60, one for each respective lead wire of extension harness 42 as shown in FIG. 3B. While extension harness 42 and locking cover 40 are illustrated as being associated with central metallic rail section 22, extension harness 42 and locking cover 40 may, alternatively, be positioned within top or bottom metallic rail sections 20, 24, and/or travel along multiple sections of rail system rail system 16, including first and second grounding bars 26, 28, based on design specifications.

FIG. 3A is a schematic view of the rear or back side of an exemplary PV module 18 of PV system 10. According to one embodiment, each PV module 18 is an AC module that includes a low voltage DC module 62 and an integral DC-AC micro-inverter 64 disposed within a metallic housing 66. DC module 62 is coupled to micro-inverter 64 by a set of DC leads 68. In one example, PV module 18 is constructed to produce 240 volts of AC power. In other examples, PV module 18 may be constructed to produce 120 volts of AC power or three phase 208 volt AC power. According to various embodiments, PV module 18 is constructed to have a maximum DC voltage less than the UL safety limit of 48 volts DC, such as, for example, 30 volts.

Each PV module 18 includes a metallic frame 70 to which the metallic housing 66 of micro-inverter 64 is attached. While FIG. 3A illustrates housing 66 attached to one of the longer, vertical sides of frame 70, one skilled in the art will recognize that housing 66 may be attached to one of the shorter, horizontal sides of frame 70 and at alternative locations along the length of frame 70 based on design specifications.

In one embodiment, metallic housing 66 is mechanically and electrically attached to metallic frame 70 of its corresponding PV module 18 by a metallic frame attachment bracket 72 using a connector assembly 74 that includes a bolt 76, a star washer 78, and a locking nut (not shown). When connector assembly 74 is tightened, star washer 78 cuts through the anodization of metallic frame 70 and creates an electrical bond between metallic housing 66 of micro-inverter 64 and metallic frame 70. A second connector assembly 80 locks metallic housing 66 in position on metallic frame 70. According to various embodiments, second connector assembly 80 may be a fastener similar to connector assembly 74 or a self tapping screw. In alternative embodiments, metallic housing 66 is directly coupled to frame 70 absent a metallic frame attachment bracket.

PV module 18 includes an AC module wiring harness 82 coupled to the output of micro-inverter 64. AC wiring harness 82 includes four lead wires: two (2) AC lead wires 84, 86, a neutral lead wire 88, and a micro-inverter ground lead wire 90 as shown in FIG. 3B. In an embodiment where PV module 18 has a 240 volt AC output, AC lead wires 84, 86 are 120 volt AC leads. A first end 92 of ground lead wire 90 is connected to a ground lug 94 inside metallic housing 66. Ground lead wire 90 is electrically connected to metallic frame 70 through the connection between metallic frame attachment bracket 72 and metallic frame 70. AC module wiring harness 82 thus provides ground continuity. Also, if micro-inverter 64 of PV module 18 is unplugged from extension harness 52, the overall system ground connection remains intact. Therefore, ground lead wire 90 in AC module wiring harness 82 is electrically connected to metallic frame 70 in a manner that meets NEC specifications.

AC module wiring harness 82 includes a connector 96 constructed to interface with AC module wiring harness 82. Connector 96 may be mounted onto frame 70 or hang loose from PV module 18, according to various embodiments. In one embodiment connector 96 is a “plug and play” connector having a pair of AC voltage pins 98, 100, a neutral pin 102, and a DC ground conductor pin 104 that correspond with the respective lead wires 84-90 of AC module wiring harness 82. For example, a second end 106 of ground lead wire 90 is coupled to ground conductor pin 104. Plug and play connector 96 is constructed to interface with respective slots 54-60 of plug and play connector 52 of AC extension harness 42 (FIG. 2) that receive pins 98-104. As used herein “plug and play” connectors refer to connectors that include wire terminations in the form of one of pins or slots, with a female plug and play connector having slots and a male plug and play connector having pins. Connection between the female and male plug and play connectors is made by plugging the two components together, thereby permitting a quick, reliable connection without hand-wiring the individual lead wires of two wire harnesses together. While connector 96 of AC module wiring harness 82 is described herein as including pins 98-104 and extension harness 42 is described as including attachment slot 108, the pins and slots can be located on either connector 96 or extension harness 42.

While rail system 16 acts to mechanically hold PV modules 18 in position, the physical contact between rail system 16 and PV modules 18 does not create an electrical connection between rail system 16 and PV modules 18 due to the anodized surfaces of the metallic frame 70 PV modules 18 and top, central, and bottom rail sections 20, 22, 24. As such rail system 16 is not automatically connected to the ground lead wire 90 in AC module wiring harness 82 or the ground lead wire 50 of extension harness 42. The ground connection is instead made in a switch connector box 110 mounted to rail system 16.

In an exemplary embodiment, switch connector box 110 is mounted to top metallic rail section 20, as shown in FIG. 1. Alternatively, switch connector box 110 may be mounted to one of the other rail sections 22, 24 or one of the grounding bars 26, 28. As one skilled in the art will recognize, the location of switch connector box 110 may be determined based on design specifications.

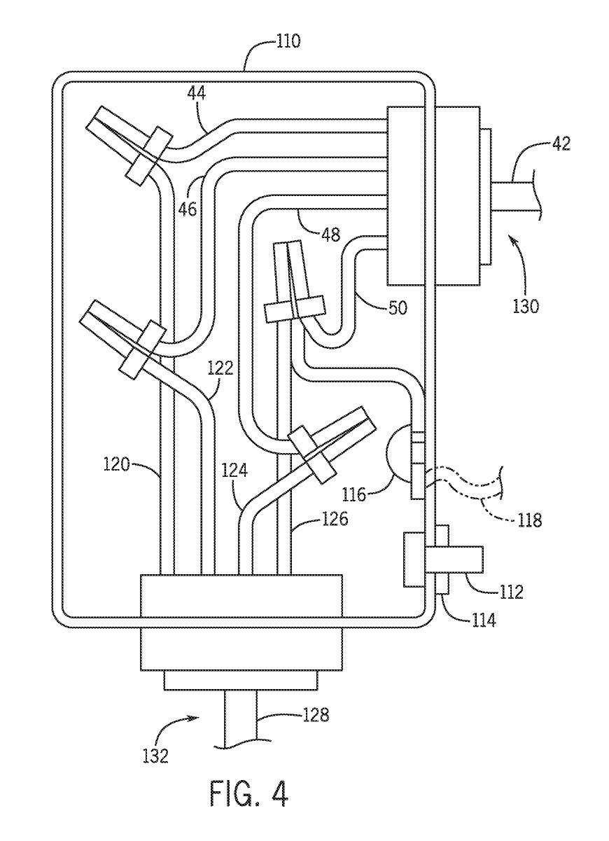

FIG. 4 illustrates a schematic view of switch connector box 110, which may be a constructed of a metal or non-metal material according to various embodiments. In embodiments where switch connector box 110 is metallic, switch connector box 110 is coupled to rail system 16 (FIG. 1) using a fastener assembly 112, similar to fastener assemblies 30 (FIG. 2), that includes a star washer 114 that penetrates the anodized surface of rail system 16, thereby forming an electrical connection between a ground lug 116 coupled to an inside surface of switch connector box 110 and rail system 16. In embodiments where switch connector box 110 is non-metallic, ground lug 116 is electrically coupled to rail system 16 using an optional wired connection 118 (shown in phantom) between ground lug 116 and rail system 16.

FIG. 4 illustrates the wiring connections made within switch connector box 110 between lead wires 44, 46, 48, 50 of extension harness 42 and corresponding AC lead wires 120, 122, a neutral lead wire 124, and a ground lead wire 126 of a home run cable 128, which feeds the electrical current from PV modules 18 of basic building block assemblies 12, 14 to a building load panel, such as, for example, a conventional 15 amp circuit breaker panel. To make the connections, a first end 130 of extension harness 42 and a first end 132 of home run cable 128 are fed into switch connector box 110. As shown, ground lead wire 50 of extension harness 42 and ground lead wire 126 of home run cable 128 are spliced and electrically connected to a ground lug 116 that is coupled to an inside surface of switch connector box 110, thereby completing the ground connection between rail system 16 and extension harness 42, and by extension, the ground connection with metal components of PV modules 18. According to one embodiment, extension harness 42 includes AWG12 wire and the home run cable 128 includes AWG10 wire for AC lead wires 120, 122 and AWG8 wire for ground lead wire 126.

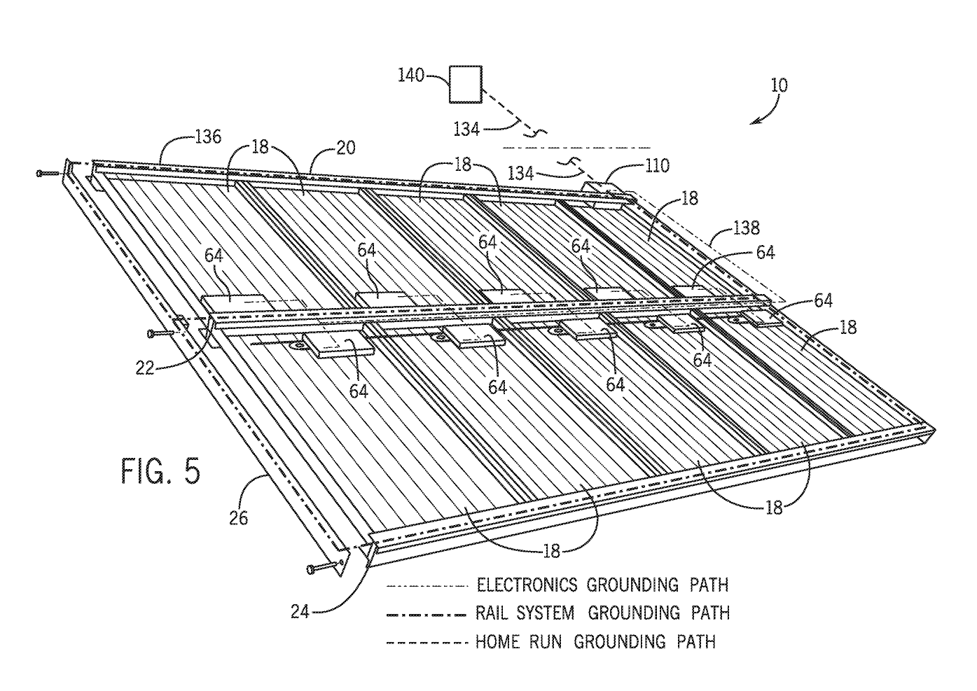

FIG. 5 illustrates the grounding paths of PV system 10, which includes a home run grounding path 134, a rail system grounding path 136 for first and second grounding bars 26, 28 and rail sections 20, 22, 24, and an electronics grounding path 138 for micro-inverters 64 of PV modules 18.

Home run grounding path 134 is formed through an electrical connection between a building load panel or circuit breaker panel 140 and switch connector box 110. Rail system grounding path 136 is formed by the electrical connection between switch connector box 110 and the support bars of rail system 16 (i.e., first and second grounding bars 26, 28 and rail sections 20, 22, 24). As such, rail system grounding path 136 travels through all of the metal components of rail system 16. Since rail system 16 is at equipotential and rail system grounding path 136 travels through all of the metal components of rail system 16, switch connector box 110 is electrically coupled to rail system grounding path 136 at a single connection point on rail system 16 without individual wired connections between each individual component of rail system 16 and switch connector box 110.

Electronics grounding path 138 is formed by the electrical connection between switch connector box 110 and PV modules 18. Specifically, electronics grounding path 138 extends through metallic frame 70 of a respective PV module 18, through metallic frame attachment bracket 72, through metallic housing 66 of micro-inverter 64, through ground lead wire 90 of micro-inverter 64, through ground lead wire 50 of extension harness 42, and to ground lug 116 within switch connector box 110. Because PV modules 18 are electrically isolated from one another by the anodized surface coating of metallic frames 70 and lack weebs or other wired connections between adjacent modules, electronics grounding path 138 is absent a direct electrical connection between PV modules 18.

The electrical connection between home run grounding path 134, rail system grounding path 136, and electronics grounding path 138 is completed within switch connector box 110. As shown in FIG. 4, ground lead wire 126 of home run cable 128 is electrically coupled to extension harness 42 by way of the grounded connection between ground lead wire 50 of extension harness 42 and ground lug 116. Ground lug 116 is electrically coupled to rail system 16 either through fastener assembly 112, in embodiments with a metallic switch connector box 110, or optional wired connection 118 in embodiments with a non-metallic metallic switch connector box 110.

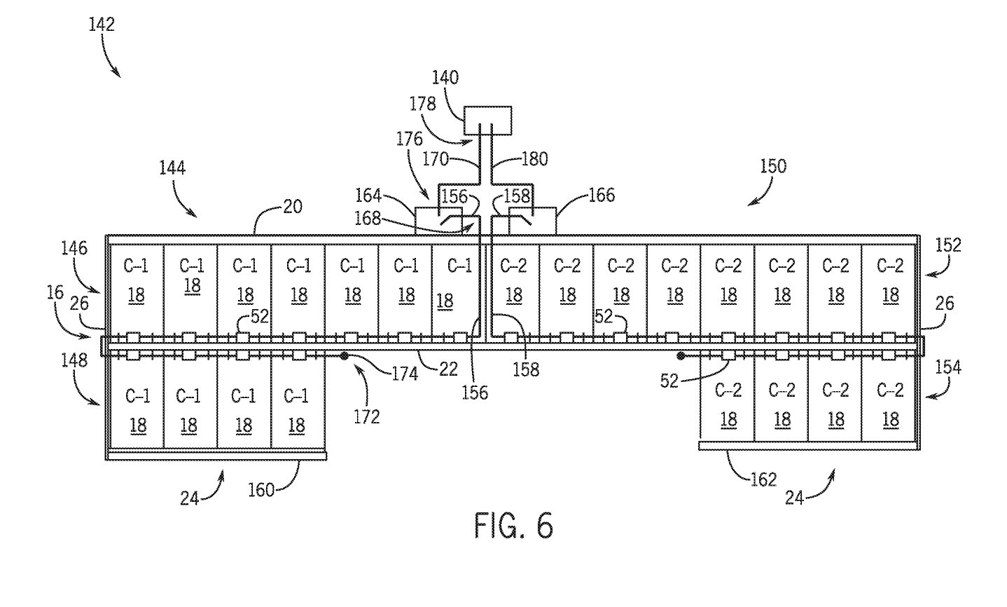

A multi-circuit PV system 142 is illustrated in FIG. 6 according to another embodiment of the invention. As multi-circuit PV system 142 includes a number of components similar to components shown in PV system 10 of FIGS. 1-4, part numbers used to indicate components in FIGS. 1-5 will also be used to indicate similar components in FIG. 6.

Multi-circuit PV system 142 of FIG. 6 includes a first circuit (C-1) 144, which includes a first pair of building block assemblies 146, 148, and a second circuit (C-2) 150, which includes a second pair of basic building block assemblies 152, 154. Each building block assembly 146, 148, 152, 154 includes a number of PV modules 18 arranged in rows and electrically connected to a connector 52 of a respective extension harness 156, 158, similar to extension harness 42 of FIG. 2, which is connected to each PV module 18 within its respective circuit 144, 150. As one skilled in the art will recognize, the number of PV modules 18 within a single circuit may vary from that illustrated in FIG. 6 and may be selected based on design specifications, such as, for example, the size of the protection circuit breaker in the load panel, and by the NEC. In one embodiment, each circuit 144, 150 includes 10-13 PV modules 18. Likewise, PV modules 18 may be arranged in alternative configurations in each circuit. For example, PV modules 18 may be arranged in a single row, or more than two rows. In any of these configurations, PV modules 18 are supported by n+1 rail sections, where n is the number of rows of PV modules 18.

PV modules 18 are mechanically held in place by rail system 16, which includes a top metallic rail section 20, a central metallic rail section 22, and bottom metallic rail section 24, which includes a first portion 160 corresponding to first circuit 144 and a second portion 162 corresponding to second circuit 150 in the embodiment illustrated in FIG. 6. First grounding bar 26 and second grounding bar 28 are mechanically and electrically coupled to rail sections 20, 22, 160, 162 by fastener assemblies 30 (FIG. 1), which penetrate the anodized coating of the components of rail system 16 and form an equipotential electrical connection therebetween.

Each circuit 144, 150 includes a respective switch connector box 164, 166, similar to switch connector box 110 of FIG. 1, electrically and mechanically coupled to top metallic rail section 20. A first end 168 of extension harness 156 from first circuit 144 enters into switch connector box 164 and is electrically connected with respective lead wires of a first home run cable 170 to create a current path from first circuit 144 to a building load panel or circuit breaker panel 140. A second end 172 of extension harness 156 ends at a termination point 174 located adjacent the last PV module 18 of building block assembly 148. As shown, a first end 176 of home run cable 170 is mechanically connected to switch connector box 164 and a second end 178 of home run cable 170 interfaces with circuit breaker panel 140.

Extension harness 158 from second circuit 150 enters switch connector box 166 in a similar manner and is connected to respective lead wires of a second home run cable 180 that creates a current path from second circuit 150 to the building load or circuit panel 140. Wired connections between extension harness 156 and first home run cable 170 and extension harness 158 and second home run cable 180 are made in a similar manner as set forth in FIG. 4.

Beneficially, embodiments of the invention thus provide a simplified system for grounding a photovoltaic system. As described above, PV modules 18 are constructed with a micro-inverter 64 that includes a ground lead that is electrically coupled to the metallic housing 66 of micro-inverter 64 and metallic frame 70 of PV module 18. An AC module wiring harness 82 carries the ground of the metallic components of the PV module 18 to an extension harness 42, which includes a ground lead and slotted connections for each PV module within the respective circuit. Ground connections for the metallic components within PV modules 18 may therefore be made during installation by simply plugging the AC module wiring harness 82 of a respective PV module 18 into a slotted connector 52 of the extension harness 42 during installation, rather than using individually placed wires or weebs to ground each individual metallic component of the PV module 18 on-site during the installation process. Likewise, ground connections for each of the metallic components of the rail system 16 of PV system 10 is accomplished on-site during installation simply by fastening the various components of the rail system 16 together, since the star washers 38 penetrate the anodized surface of rail sections 20, 22, 24 and grounding bars 26, 28 when the components are fastened together. As such, the metallic components of rail system 16 are at equipotential and may be connected to the ground lead of extension harness 42 through a single connection point in switch connector box 110, as described above.

In summary, the design of the grounding system described herein significantly simplifies the on-site installation procedure for grounding the metallic components within a PV system by providing a single plug-and-play type connection that grounds the PV modules to the extension harness and an equipotential rail system that may be connected to ground through a single connection point.

Therefore, according to one embodiment of the invention, a photovoltaic (PV) grounding system includes a first grounding path comprising an electrical connection between a plurality of support bars of a rail system and a connection box coupled to the rail system. The PV grounding system also includes a second grounding path comprising an electrical connection between the connection box and a plurality of PV modules disposed within the rail system, the second ground path extending from micro-inverter ground leads of the plurality of PV modules, through an extension harness electrically connected to the plurality of PV modules, to a ground connection within the connection box. The PV grounding system further includes a third grounding path that includes an electrical connection between the ground connection within the connection box and a building load panel. The first grounding path, the second grounding path, and the third grounding path are electrically connected within the connection box.

According to another embodiment of the invention, a method of manufacturing a photovoltaic (PV) grounding system includes providing a first PV panel having a frame, electrically coupling a metal housing to the frame of the first PV panel, the metal housing having a micro-inverter disposed therein, and coupling a first end of a micro-inverter ground lead to the metal housing. The method also includes assembling a plurality of support bars to form an equipotential rail system, positioning the first PV panel within the rail system, and coupling a second end of the micro-inverter ground lead to an extension harness, the extension harness including a plurality of connection modules electrically coupled to an extension ground lead of the extension harness. The method further includes coupling a connector box to the rail system such that the connector box is at equipotential with the rail system, positioning a first end of the extension harness within the connector box, positioning a load ground lead of a load panel within the connector box, and coupling the load ground lead to the extension ground lead within the connector box.

According to yet another embodiment of the invention, a photovoltaic (PV) system includes an equipotential rail system and a first PV circuit. The first PV circuit includes a first multi-module wiring harness disposed within the rail system, a first plurality of PV modules disposed within the rail system, each of the first plurality of PV modules having an internal ground lead electrically coupled to the first wiring harness, and a first connection box mechanically and electrically coupled to the rail system and a ground lead wire of the first wiring harness. The PV system further includes a first home run cable comprising a first end and a second end, the first end mechanically and electrically coupled to the first connection box, and the second end coupled to a ground connection of a circuit breaker panel.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

What is claimed is:

1. A photovoltaic (PV) system comprising:
an equipotential rail system comprising a plurality of support bars; and
a first PV circuit comprising:
a first wiring harness disposed adjacent the equipotential rail system, the first wiring harness comprising a ground lead wire and a plurality of connectors coupled to the ground lead wire;
a first plurality of PV modules disposed within the equipotential rail system, each of the first plurality of PV modules having a micro-inverter ground lead electrically coupled to the ground lead wire through a respective connector of the plurality of connectors of the first wiring harness; and
a first connector box mechanically and electrically coupled to the equipotential rail system and the ground lead wire of the first wiring harness.

2. The PV system of claim 1 wherein the internal ground lead of each of the first plurality of PV modules is electrically coupled to a micro-inverter housing and a frame of the respective PV module.

3. The PV system of claim 1 wherein each of the first plurality of PV modules comprises an AC wiring harness, the AC wiring harness comprising:
a pair of AC lead wires;
a neutral lead wire; and
the micro-inverter ground lead wire.

4. The PV system of claim 1 further comprising a second PV circuit comprising:
a second multi-module wiring harness disposed within the equipotential rail system;
a second plurality of PV modules disposed within the equipotential rail system, each of the second plurality of PV modules having a micro-inverter ground lead electrically coupled to the second wiring harness; and
a second connector box mechanically and electrically coupled to the equipotential rail system.

5. The PV system of claim 1 wherein a first PV module of the first plurality of PV modules is positioned directly adjacent a second PV module of the first plurality of PV modules; and
wherein a frame of the first PV module is electrically isolated from a frame of the second PV module.

6. The PV system of claim 1 wherein the first rail system comprises:
a bottom rail section;
a top rail section;
a center rail section disposed between the bottom rail section and the top rail section;
a first grounding bar coupled to respective first ends of the bottom, top, and center rail sections; and
a second grounding bar coupled to respective second ends of the bottom, top, and center rail sections; and
wherein the bottom, top, and center rail sections and the first and second grounding bars are at equipotential.

7. The PV system of claim 6 wherein the first plurality of PV modules comprises a first row of PV modules and a second row of PV modules;
wherein the first row of PV modules is positioned between the bottom rail section and the center rail section; and
wherein the second row of PV modules is positioned between the center rail section and the top rail section.

8. The PV system of claim 6 wherein the first rail system comprises a plurality of fasteners that penetrate an anodized surface of the first rail system and electrically couple the bottom rail section, top rail section, center rail section, first grounding bar, and second grounding bar.

9. The PV system of claim 1 wherein the micro-inverter ground lead of each of the first plurality of PV modules is disposed within a respective module wiring harness having a plug and play connector that interfaces with a corresponding plug and play connector on the first wiring harness.

10. A method of manufacturing a photovoltaic (PV) grounding system comprising:
assembling a plurality of support bars to form an equipotential rail system;
positioning a first PV panel within the equipotential rail system, the first PV panel having a micro-inverter ground lead coupled thereto;
coupling the micro-inverter ground lead to an extension ground lead of an extension harness disposed adjacent the equipotential rail system via one of a plurality of connectors of the extension harness;
coupling a connector box to the equipotential rail system such that the connector box is at equipotential with the equipotential rail system; and
coupling the extension ground lead of the extension harness to a load ground lead of a load panel within the connector box.

11. The method of claim 10 further comprising coupling the housing of the micro-inverter to a frame of the first PV panel with at least one fastener that penetrates an anodized surface of the frame.

12. The method of claim 10 wherein coupling the second end of the micro-inverter ground lead to the extension harness comprises coupling a plug and play connector coupled to an output of the micro-inverter with a plug and play connector located on the extension harness.

13. The method of claim 10 wherein assembling the plurality of support bars comprises coupling a plurality of horizontal support members to a plurality of vertical support members with a plurality of fasteners that penetrate anodized surfaces of the horizontal and vertical support members to create an electrical connection therebetween.

14. The method of claim 10 further comprising:
providing a second PV panel having a frame;
positioning the second PV panel within the rail system directly adjacent the first PV panel; and
electrically isolating the frame of the first PV panel from the frame of the second PV panel.

15. A photovoltaic (PV) system comprising:
a rail assembly comprising a plurality of rail sections at equipotential;
a connector box coupled to the rail assembly;
a wire harness disposed adjacent a rail section of the rail assembly, the wire harness comprising a plurality of connection modules electrically coupled to a ground lead wire; and
a PV module mounted to the rail assembly and comprising an internal ground lead electrically coupled to a ground connection within the connector box through a respective connection module of the plurality of connection modules.

16. The PV system of claim 15 wherein the plurality of connection modules are electrically coupled to a pair of AC lead wires and a neutral lead wire of the wire harness.

17. The PV system of claim 16 wherein the PV module comprises:
a frame; and
a DC-AC micro-inverter provided within a housing mounted to the frame; and
wherein the internal ground lead of the PV module extends out from the housing and is electrically coupled to the ground lead wire of the wire harness.

18. The PV system of claim 17 wherein the internal ground lead of the PV module is provided within an AC wiring harness having a first end coupled to the housing of the DC-AC micro-inverter and a second end constructed to couple with a connection module of the plurality of connection modules.

19. The PV system of claim 18 wherein the AC wiring harness further comprises a pair of AC lead wires and a neutral lead wire.

20. The PV system of claim 15 wherein the rail assembly comprises an upper rail section, a lower rail section, and a pair of side rail sections oriented perpendicular to the upper rail section and the lower rail section; and
wherein the PV module is positioned between the upper rail section and the lower rail section.
